(19) United States
(12) Patent Application Publication
(10) Pub. No.: US 2008/0070411 A1
(43) Pub. Date: Mar. 20, 2008

(54) METHODS FOR UNIFORMLY ETCHING FILMS ON A SEMICONDUCTOR WAFER

(76) Inventors: John Ghekiere, Kalispell, MT (US); Marvin Bernt, Kalispell, MT (US)

Correspondence Address: PERKINS COIE LLP/SEMITOOL, PO BOX 1208, SEATTLE, WA, 98111-1208, US

(21) Appl. No.: 11/533,450

(22) Filed: Sep. 20, 2006

(51) Int. Cl. H01L 21/302

(52) U.S. Cl. 438/689

(57) ABSTRACT

A chemical mixture etches chemically different materials, layers, or films on the surface of a semiconductor wafer or other workpiece at approximately the same rate. The different layers may include, for example, a first material, having a first chemical composition, encapsulated within or sandwiched between one or more materials having chemical compositions different from the first material. For example, a TiN layer may be encapsulated within or sandwiched between two or more TEOS layers. By etching away the different layers at approximately the same rate, undercutting of the encapsulated or sandwiched layer is substantially or entirely prevented. Flaking, liftoff, and similar defects are avoided.

### BACKGROUND

At various stages of semiconductor device manufacturing, two or more chemically different materials, layers, or films are often on the surface of a silicon wafer or other workpiece. One layer or film having a first chemical composition may, for example, be encapsulated within or sandwiched between layers or films of another material having a second chemical composition. For example, it is common for an outer surface of a silicon wafer to have a layer or film of titanium-nitride (TiN) encapsulated within or sandwiched between two or more layers or films of silicon dioxide derived from tetra-ethyl-ortho-silicate gas (TEOS).

It is generally desirable to remove portions of these and other layers or films via an etching process or similar technique, typically near the relatively unstable edge region of the wafer. Indeed, it is advantageous to remove each of the layers or films, on at least the front side of the wafer, up to a specified distance inwardly from the wafer edge.

A three-step process is commonly used to etch away the layers. Continuing with the example above, first, hydrofluoric acid (HF) is used to etch away areas of the outer or upper TEOS layer. An ammonium hydroxide (NH₄OH) and hydrogen peroxide (H₂O₂) mixture is then used to etch away areas of the TiN layer, after which HF is applied to etch away areas of the inner or lower TEOS layer, as well as any other layers or films on the wafer.

Unfortunately, the first HF etching step also tends to etch away the inner TEOS layer, since the inner TEOS layer is typically partially exposed at the outer edge of the wafer. Furthermore, due to their chemical composition, the TEOS layers are typically more easily etched than the TiN layer. As a result, portions of the inner TEOS layer tend to be etched away from underneath the TiN layer. When this undercutting of the TiN layer occurs, support for the outer regions of the TiN layer is lost, which may cause portions of the TiN layer to flake off or lift away. This can cause damage to devices constructed on the wafer. Thus, a need exists for an improved method of etching away chemically different materials or layers on a wafer or similar workpiece surfaces.

### SUMMARY

A remarkable new chemical mixture and process has now been developed. With this new chemical mixture and process, undercutting of layers is greatly reduced or avoided entirely. The problems caused by unequal etching using existing mixtures and methods are consequently overcome. A chemical mixture, which may include an oxidizing agent and a halogen or fluorine component, may be used for etching away, at approximately the same rate, chemically different materials, layers, or films residing on the surface of a semiconductor wafer or other workpiece. The different layers may include, for example, a first material, having a first chemical composition, encapsulated within or sandwiched between one or more materials having chemical compositions different from the first material. The chemical mixture etches away the different layers at approximately the same rate. As a result, undercutting of the encapsulated or sandwiched layer is substantially or entirely prevented.

Other features and advantages will appear hereinafter. The features described above can be used separately or together, or in various combinations of one or more of them. Sub-combinations of the features described are also contemplated. Many of the method steps described herein may be performed in an order different than that which is explicitly described.

### BRIEF DESCRIPTION OF THE DRAWINGS

In the drawings, wherein the same reference number indicates the same element throughout the several views:

FIGS. 1A-1E illustrate a step-by-step process for etching chemically different layers on a wafer, according to one embodiment.

FIG. 2 is a table including strip rate data produced by an etching process used for stripping various films from a wafer using a chemical mixture of hydrogen peroxide, ammonium fluoride, and hydrofluoric acid.

### DETAILED DESCRIPTION OF THE DRAWINGS

Various embodiments of the invention will now be described. The following description provides specific details for a thorough understanding and enabling description of these embodiments. One skilled in the art will understand, however, that the invention may be practiced without many of these details.

To overcome problems associated with film or layer undercutting on a wafer, an improved etching process is performed using a chemical mixture that etches the different layers on a workpiece, such as a silicon semiconductor wafer, at approximately the same rate. While the term “wafer” will be used from this point forward, the processes described herein may be applied to any workpiece including layers or films of different materials on one or more surfaces of the workpiece. These workpieces may include semiconductor wafers, memory disks, optical media, and other substrates on which micro-electronic, micro-mechanical or micro-electromechanical devices are or can be formed.

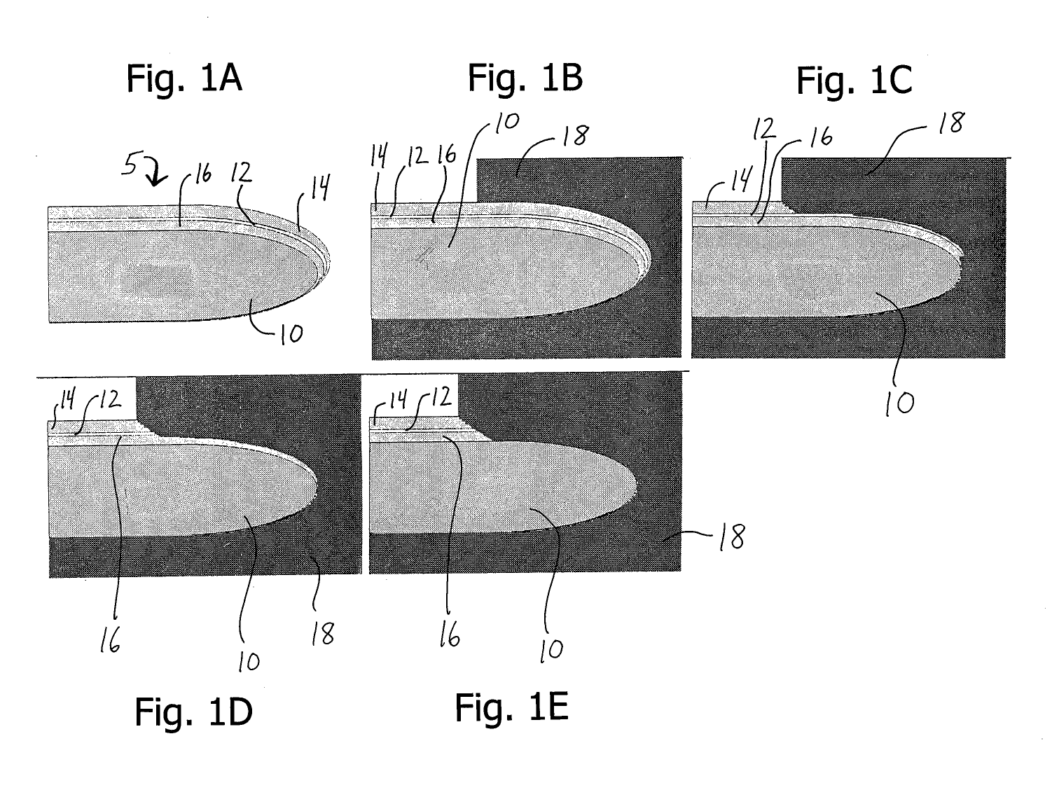

FIG. 1A is a partial side-sectional view of an exemplary wafer 5. The wafer 5 includes a substrate 10 made of silicon or another suitable material. A layer or film 12 of TiN is encapsulated within or sandwiched between an outer or upper layer or film 14 of TEOS and an inner or lower layer or film 16 of TEOS, which resides on an outer surface of the substrate 10. While the TiN layer 12 and TEOS layers 14, 16 are described here, the processes described here may be used to etch other chemically dissimilar materials on one or more surfaces of a wafer. Thus, the silicon substrate 10 including TEOS and TiN films is described only by way of example. The methods described here can of course also be used on wafers having layers of various other materials as well.

At the outset of the etching process, the wafer 5 may be loaded into a processing chamber or other suitable vessel in which the wafer 5 may be etched or otherwise processed. The wafer 5 may be loaded via a robot or other suitable loading device, which optionally secures the wafer to a workpiece holder, such as a rotor or chuck, a stationary stage, or another rotatable or fixed support. Once the wafer 5 is secured, the etching process may begin.

A chemical mixture 18 suitable for etching the TiN layer 12 and the TEOS layers 14, 16, at approximately the same rate, is delivered or otherwise applied to the wafer 5. The mixture may be sprayed, jetted, applied in bulk, or applied as a vapor. Immersion, full or partial, may also be used. The chemical mixture 18 preferably etches or strips the chemically different layers at rates that differ by less than 15%, more preferably by less than 10%.

The chemical mixture 18 may be sprayed or otherwise delivered to the wafer 5 from nozzles or another fluid delivery mechanism in the processing chamber. The chemical mixture 18 is preferably delivered at or around the edge region of the wafer 5, as shown in FIG. 1B, for removing portions of the TiN layer 12 and the TEOS layers 14, 16 at the outer edge of the substrate 10.

The chemical mixture 18 preferably includes at least an oxidizing agent and an acid component, such as fluorine or other halogen. Other chemical mixtures suitable for etching the specific chemically different layers or films present on a wafer may alternatively be used. Examples of chemical mixtures suitable for etching the TiN layer 12 and the outer and inner TEOS layers 14, 16, at approximately the same rate, include the following:
Mixture 1: hydrogen peroxide (H₂O₂)+ammonium fluoride (NH₄F)+hydrofluoric acid (HF);
Mixture 2: deionized water (DI)+ammonium persulfate ((NH₄)₂S₂O₈)+hydrofluoric acid (HF).

In Mixture 1, hydrogen peroxide is the oxidizing agent. The ratio of hydrogen peroxide to ammonium fluoride to hydrofluoric acid in Mixture 1 may be approximately 100:1.0:0.138. This ratio has been found to provide approximately equal etching rates of the chemically different layers on a wafer, such as TiN and TEOS layers. This ratio is exemplary only, however, and may be modified to achieve desired results. For example, each of the ratio numbers given above may be varied by ±5, 10, 20 or 30%. Depending on the water content of these chemical solutions as provided from the manufacturer, de-ionized water may be added as needed to achieve the desired overall concentrations. Surfactants and detergents may also be added.

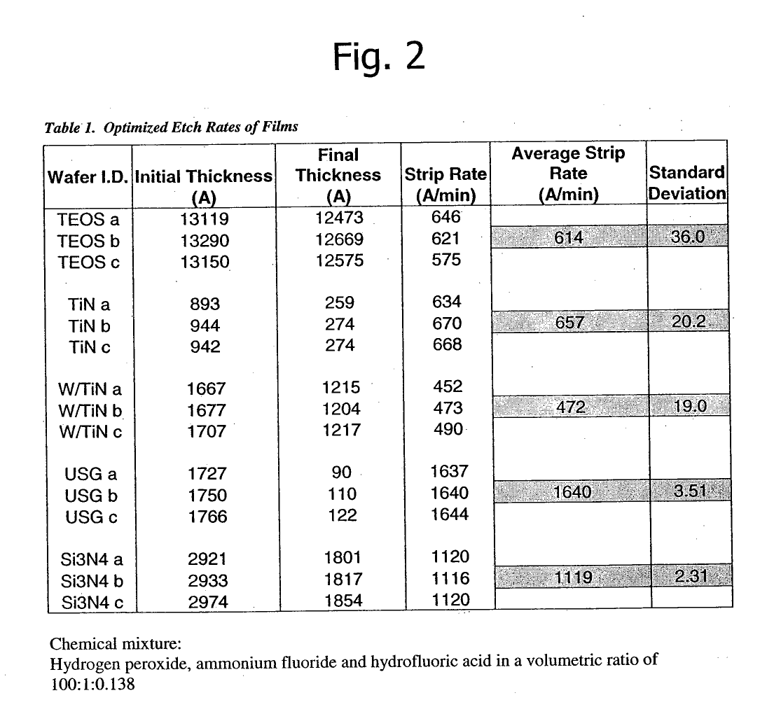

FIG. 2 is a table showing etch rate or strip rate results achieved using this ratio of Mixture 1 on wafers having a variety of films or layers. Applying Mixture 1 to a TEOS layer, for example, produced an average strip rate of 614 Å/min, while application of Mixture 1 to a TiN layer produced an average strip rate of 657 Å/min. Thus, the strip rates of the TEOS and TiN layers differed by approximately only 7%.

In Mixture 2, ammonium persulfate is the oxidizing agent. The ratio of deionized water to ammonium persulfate to hydrofluoric acid in Mixture 2 is preferably approximately 100:5.0:0.10. This ratio has been found to provide approximately equal etching rates of the chemically different layers on a wafer, such as TiN and TEOS layers. This ratio is exemplary only, however, and may be modified to achieve desired results. Again, these ratios may be varied in the same way as with mixture 1.

As shown in FIGS. 1C-1E, the chemical mixture 18 begins to etch away the outer TEOS layer 14 more quickly than it does the TiN layer 12 and the inner TEOS layer 16. This is a result of the outer TEOS layer 14 having a much greater surface area exposed upon initial delivery of the chemical mixture 18. Thus, while the chemical mixture 18 immediately begins etching the TiN layer 12 wherever it is exposed, the outer TEOS layer 14 is removed more quickly due to the greater surface area initially exposed to the chemical mixture 18. Similarly, while the chemical mixture 18 immediately begins etching the inner TEOS layer 16 wherever it is exposed, the TiN layer 12 is removed more quickly because it has a greater surface area exposed to the chemical mixture 18, due to the removal of the outer TEOS layer 14 above the TiN layer 12. As a result, the outermost or uppermost layers are etched away more quickly than are the layers beneath them, and undercutting of the various layers is therefore substantially or entirely prevented.

In the situation where the TiN layer 12 is encapsulated within two TEOS layers 14, 16, it is acceptable for the chemical mixture 18 to strip the individual TEOS layers 14, 16 up to approximately twice as fast as it strips an individual TiN layer 12. This is because, as the TEOS layers 14, 16 are stripped away at the faster rate, both the upper and lower surfaces of the TiN layer 12 become exposed to the chemical mixture 18. Thus, the combined strip rate of the TiN layer 12 from both sides is essentially double the strip rate of a single side of the TiN layer 12. Accordingly, a chemical mixture 18 that strips the TEOS layers 14, 16 at a higher rate than the TiN layer 12 (up to approximately twice as fast) may be used to increase etching efficiency. For example, a chemical mixture 18 that strips a TEOS film at approximately 600 Å/min, and a TiN film at approximately 300 Å/min, could be used to efficiently remove an encapsulated TiN layer 12 at approximately the same rate as the surrounding TEOS layers 14,16.

By using a chemical mixture that etches away the chemically different layers or films on a wafer at approximately the same rate, undercutting and the resultant flaking away of one or more of the layers is prevented. Furthermore, the use of a single chemical mixture that can be applied in a one-step process for etching chemically different layers or films on a wafer is more efficient than, and reduces system complexity relative to, traditional multi-step etching processes. Indeed, a traditional etching process requiring the application of different etching chemicals, delivered in sequential steps, to remove chemically different layers on a wafer, is generally more time-consuming than the processes described herein. Thus, the described processes can improve etching efficiency and overall processing times.

The processes described here may be used to etch films on one or more sides of a semiconductor wafer or other workpiece. A chemical mixture including an oxidizing agent and a fluorine component may be used for etching certain film combinations, such as a TiN film encapsulated within or sandwiched between two or more TEOS films. Other chemical mixtures may similarly be made suitable for etching a given combination of films or layers at approximately the same rate. Essentially, any chemical mixture suitable for etching a given combination of layers or films of different materials at rates that substantially prevent undercutting of the layers or films, particularly the encapsulated or sandwiched layer or film, is contemplated. Apart from TiN films, the methods may also be used for etching other metal films, including non-aluminum metal films or layers. The methods may also be used for etching multi-layer structures, for example, structures having 2, 3, 4 or more layers. In some applications, an oxide film removing component may be added to the mixture, or separately applied in advance, to remove an oxide layer which might interfere with etching. The process may be performed in spin-spray apparatus, in a single wafer mode, for example as described in U.S. Pat. No. 6,632,292, incorporated herein by reference, or in a batch process mode, as described for example in U.S. Pat. No. 6,871,665 or 6,799,932, both also incorporated herein by reference. The liquid etchant solution may be heated, for example from 25 or 30° C. up to about 99° C. in an ambient pressure process chamber.

The words used here are intended to be interpreted in their broadest reasonable manner, even though they are used with a detailed description of certain specific embodiments of the invention. Any words intended to be interpreted in any restricted way, however, will be specifically defined in this detailed description section.

Where the context permits, singular or plural terms may also include the plural or singular term, respectively. Moreover, unless the word “or” is expressly limited to mean only a single item exclusive from the other items in a list of two or more items, then the use of “or” in such a list is to be interpreted as including (a) any single item in the list, (b) all of the items in the list, or (c) any combination of items in the list.

While several embodiments have been shown and described, various changes and substitutions may of course be made, without departing from the spirit and scope of the invention. Many of the method steps described herein, for example, may be performed in a different order than that which is explicitly described. Moreover, many of the embodiments described herein may be used separately or in combination with one or more additional embodiments. The invention, therefore, should not be limited, except by any claims and their equivalents.

1. A method for etching materials on a workpiece, wherein the workpiece includes a first layer comprising a first material, a second layer, and a third layer located between the first and second layers comprising a third material, comprising:
delivering a chemical mixture, including an oxidizing agent and a fluorine component, to at least the first layer;
wherein the chemical mixture etches each of the first, second, and third layers and substantially no undercutting of the third layer occurs.

2. The method of claim 1 wherein the chemical mixture etches the first, second, and third layers at rates that differ from each other by less than 10%.

3. The method of claim 1 wherein the chemical mixture comprises hydrogen peroxide, ammonium fluoride, and hydrofluoric acid.

4. The method of claim 3 wherein the ratio of hydrogen peroxide to ammonium fluoride to hydrofluoric acid in the chemical mixture is approximately 100:1.0:0.138, plus or minus 30% of each ratio number.

5. The method of claim 1 wherein the chemical mixture comprises deionized water, ammonium persulfate, and hydrofluoric acid.

6. The method of claim 1 wherein the first layer comprises the same material as the second layer.

7. The method of claim 6 wherein the first and second layers each comprise a film of TEOS.

8. The method of claim 7 wherein the third layer comprises a film of TiN.

9. The method of claim 1 wherein the chemical mixture is delivered to an edge region of the workpiece.

10. A method for etching chemically different layers on a surface of a wafer, comprising:
applying a chemical mixture, including an oxidizing agent and a fluorine component, to at least one of the chemically different layers;
wherein the chemical mixture etches each of the different layers at approximately the same rate, to prevent undercutting of the different layers.

11. The method of claim 10 wherein the chemical mixture is applied to an outermost layer of the chemically different layers, such that the chemical mixture initially etches the outermost layer, and then proceeds to simultaneously etch portions of the outermost layer and one or more of the chemically different layers underlying the outermost layer.

12. The method of claim 10 wherein the oxidizing agent comprises hydrogen peroxide or ammonium persulfate.

13. The method of claim 10 wherein the chemical mixture comprises a mixture of hydrogen peroxide, ammonium fluoride, and hydrofluoric acid or a mixture of deionized water, ammonium persulfate and hydrofluoric acid.

14. The method of claim 10 wherein the chemically different layers comprise a layer of TiN encapsulated within or sandwiched between a plurality of layers of TEOS.

15. The method of claim 10 wherein the chemical mixture is applied to an edge region of the wafer.

16. The method of claim 10 wherein the chemical mixture etches the chemically different layers at rates that differ by less than 10%.

17. A method for etching chemically different layers on a surface of a workpiece, comprising:
delivering to the workpiece a chemical mixture for etching each of the chemically different layers at approximately the same rate, such that substantially no undercutting of the chemically different layers occurs.

18. The method of claim 17 wherein the chemical mixture is applied to an outermost layer of the chemically different layers, such that the chemical mixture initially etches the outermost layer, and then proceeds to simultaneously etch portions of the outermost layer and one or more of the chemically different layers underlying the outermost layer.

19. The method of claim 17 wherein the chemical mixture comprises an oxidizing agent and a fluorine component.

20. The method of claim 17 wherein the chemical mixture etches each of the chemically different layers at rates that differ by less than 10%.
